(19) United States
(12) Patent Application Publication
(10) Pub. No.: US 2026/0290150 A1
(43) Pub. Date: Sep. 24, 2026

(54) HAZARD DETECTOR TESTING

(71) Applicant: NO CLIMB PRODUCTS LIMITED, Hertfordshire (GB)

(72) Inventors: Allen STUART, Hertfordshire (GB); Amee AMIN, Hertfordshire (GB); Tim LOWEN, Hertfordshire (GB); Adrian SEXTON, Hertfordshire (GB); Gareth DIBDEN, Hertfordshire (GB)

(21) Appl. No.: 19/472,596

(22) PCT Filed: Mar. 26, 2024
(86) PCT No.: PCT/GB2024/050810

§ 371 Date: Oct. 3, 2025

(30) Foreign Application Priority Data
Apr. 3, 2023 (GB) 2304952.1

(51) Int. Cl. G08B 29/14; G01R 33/00

(52) U.S. Cl. CPC G08B 29/14; G01R 33/0047; G01R 33/0076

(57) ABSTRACT

In a first aspect, a hazard detector testing system is provided that comprises: a sensing arrangement configured to detect electromagnetic radiation produced by a hazard detector; and a spacing arrangement configured to engage with the hazard detector and to maintain a predefined distance between the hazard detector and the sensing arrangement when the spacing arrangement is engaged with the hazard detector; wherein the spacing arrangement is in the form of a platform or a ring structure or includes one or more walls and/or a plurality of columns. In a second aspect, a hazard detector testing system may be provided comprising: a sensing arrangement configured to detect electromagnetic radiation produced by a hazard detector; and at least one mask arrangement comprising an opening configured to restrict a field of view of at least one sensor provided on the sensing arrangement.

### TECHNICAL FIELD

The present invention relates to testing of the operation of hazard detectors and sensing of output from a hazard detector by a hazard detector testing system.

### BACKGROUND

Hazard detection systems can utilise a variety of sensors to detect hazards, including smoke sensors, heat sensors, gas sensors, etc. Equipment to carry out functional testing of different types of hazard detector is already known. In such equipment, test stimulus can be designed to replicate the hazard in a non-hazardous fashion (e.g. heat, simulated smoke), so that the correct operation of the detector and/or the system can be verified without the risk of duplicating the real hazard (e.g. a real fire). A test system for carrying out a functional test would normally require an operator to manually activate the test system to initiate a test on a hazard detector, determine whether a test was a success by manually checking for an output from the hazard detector under test, and then manually log the result of the test. This relies on an operator correctly carrying out an assessment and can be prone to errors.

The alert or alarm signal emitted from the hazard detector may be an electromagnetic visible light signal and may be automatically sensed by a reading device on the hazard detector test system such as already disclosed in the Applicant's earlier patent application published as GB2592660 A. It is desirable to provide an improved arrangement for detecting the emitted signal from the hazard detector.

### SUMMARY OF THE INVENTION

From a first aspect, the present invention provides a hazard detector testing system comprising: a sensing arrangement configured to detect electromagnetic radiation produced by a hazard detector; and a spacing arrangement configured to engage with the hazard detector and to maintain a predefined distance between the hazard detector and the sensing arrangement when the spacing arrangement is engaged with the hazard detector.

From a second aspect, the present invention provides an apparatus for spacing a hazard detector from a hazard detector testing apparatus during a test on the hazard detector, comprising a spacing arrangement of aforementioned first aspect, configured to engage a surface of the hazard detector and to maintain a predefined distance between an emitter of electromagnetic radiation on the hazard detector and a sensing arrangement in the hazard detector testing apparatus when the hazard detector testing apparatus is positioned to carry out a test on the hazard detector.

From a third aspect, the present invention provides an apparatus for restricting a field of view of at least one sensor provided on a sensing arrangement in a hazard detecting apparatus that is to detect electromagnetic radiation emitted by a hazard detector; comprising: at least one mask arrangement comprising an opening configured to restrict a field of view of at least one sensor provided on the sensing arrangement in the hazard detector testing apparatus when the hazard detector testing apparatus is positioned to carry out a test on the hazard detector.

From a fourth aspect, the present invention provides a hazard detector testing system comprising: a sensing arrangement configured to detect electromagnetic radiation produced by a hazard detector; and at least one mask arrangement comprising an opening configured to restrict a field of view of at least one sensor provided on the sensing arrangement.

From a fifth aspect, the present invention provides a hazard detector test tool comprising: a dispenser to receive a hazard detector during a test, the dispenser further comprising the hazard detecting testing system of the aforementioned first aspect; the spacing arrangement of the aforementioned second aspect; the restricting apparatus of the aforementioned third aspect; or the hazard detecting testing system of the aforementioned fourth aspect.

Further optional features relating to these aspects of the hazard detector testing systems, spacing arrangement, and mask arrangement are provided in the appended dependent claims.

### BRIEF DESCRIPTION OF THE DRAWINGS

Examples of the invention will now be described with reference to the accompanying drawings in which:

FIG. 1 shows a view of a first example of hazard detector testing system and a hazard detector to be tested;

FIG. 2 shows a platform of the hazard detector testing system of FIG. 1;

FIG. 3 shows a mask layer of the hazard detector testing system of FIG. 1;

FIG. 4 shows a protective layer of the hazard detector testing system of FIG. 1;

FIG. 5a shows a perspective view of a cutaway portion of the mask layer of FIG. 3; and FIG. 5b shows side view of part of the cutaway portion of FIG. 5a;

FIG. 6 shows a schematic diagram of the different radiation affecting a mask layer and sensor on the sensing arrangement of FIG. 1;

FIG. 7 shows a schematic view of a second example of hazard detector testing system within which a hazard detector to be tested is located; and

FIG. 8 shows a schematic diagram of a dispensing tool that includes some or all of the elements of the hazard detector testing system of FIGS. 1 to 7.

### DETAILED DESCRIPTION

Examples described herein relate to hazard detector testing systems which are used to test hazard detectors.

Hazard detectors such as smoke, heat or gas detectors may comprise an emitter such as an illumination source that outputs visible light to indicate information relating to the hazard detector. The illumination source may be an LED or another source. In an example, the hazard detector information relates to the status of the detector such as whether the hazard detector has entered an alarm state. Alternatively, or additionally, the hazard detector information may relate to the identification of the hazard detector.

A hazard detector testing system may be used to provide test stimulus that replicates a hazard in a non-hazardous fashion, and can carry out a functional test on the hazard detector. The hazard detector testing system may comprise a tool that includes a dispenser or cup that is brought into close proximity to the hazard detector to test the detector. At least part of the dispenser or cup may be transparent.

The testing system may comprise a sensing arrangement including at least one sensor to automatically detect electromagnetic radiation, such as visible light or infrared radiation or ultraviolet radiation, emitted from the illumination source of the hazard detector. To be able to measure an intensity and spectral content of an illumination source produced by a hazard detector may require a large array of sensors in the sensing arrangement of the testing system. The sensors in the sensing arrangement may also be affected by ambient electromagnetic radiation which can lead to errors in reading.

In examples described herein, there is provided a spacing arrangement that maintains a predefined distance between a hazard detector to be tested and a sensing arrangement of a hazard detector testing system during a test when the illumination source of the hazard detector which may indicate the result of a test is to be read. The spacing arrangement is configured to be positioned in a dispenser of the hazard detector testing system. A field of view of a sensor on the sensing arrangement is an angle through which the sensor is sensitive to electromagnetic radiation. In other words, the field of view defines a maximum area of a sample that a sensor in the sensing arrangement can detect electromagnetic radiation. In an example, the spacing arrangement is configured to engage with the hazard detector and maintain a predefined distance between the hazard detector and the sensing arrangement when the spacing arrangement is engaged with the hazard detector. The predefined distance is provided to prevent the hazard detector from encroaching too far into the field of view of one or more sensors provided on the sensing arrangement. By preventing the hazard detector from encroaching too far into the sensor's field of view, the number of sensors required to fully monitor the hazard detector's surface can be reduced.

In one example, the spacing arrangement may be in the form of a platform that is positioned above the sensing arrangement when the hazard detector system is in a position to conduct a test on the hazard detector. The platform may comprise an upper surface that abuts a lowermost surface of the hazard detector to prevent movement in a direction along the axis of the hazard detector and enable a predefined distance to be maintained when the hazard detector is under test within the testing tool. The platform may be non-opaque to allow that electromagnetic radiation from the hazard detector that may be light from an illumination source from the hazard detector to be detected by the sensing arrangement. Other forms of spacing arrangement will be appreciated by the skilled person with the benefit of the present disclosure.

For example, the spacing arrangement may be in the form of ring structure mounted to and around an inner wall of a dispenser of the hazard detector testing system and above the sensing arrangement. The ring structure is capable of engaging with a surface of the hazard detector to limit the insertion depth of the detector to the sensing arrangement when a test is to be conducted. It may comprise an opening within which a lower part of the detector containing an illumination source passes through or another means to allow electromagnetic radiation from the illumination source to pass to and be detected adequately by sensors in the sensing arrangement. Other alternative mechanical spacing arrangements may include one or more walls, a plurality of columns and/or separate spacing elements within the dispenser of a testing tool that can provide separation at least at a predefined distance between a sensor and a hazard detector to be tested. The predefined distance is such that the sensors' field of view is increased as the distance between the sensor and hazard detector is increased whilst being able to adequately detect electromagnetic radiation from the hazard detector.

In an additional or alternative example, at least one mask arrangement may be provided, including an opening or aperture configured to restrict a field of view of at least one sensor provided on the sensing arrangement. The mask arrangement is configured to be positioned in a dispenser of the hazard detector testing system and may be arranged on the sensing arrangement of the hazard detector testing system. It will be appreciated to the skilled person with the benefit of the present disclosure that without the mask arrangement, the field of view of the sensor may be wider and ambient light may be more visible by the sensor compared to the examples herein which may include the mask arrangement.

In an example, the spacing arrangement and mask arrangement may be combined through mechanical connection into a single device that can be configured to be positioned within a dispenser of a hazard detector testing system and attached to the sensing arrangement. The spacing arrangement can allow for a wider field of view for sensors in the sensing arrangement (compared to an arrangement without a spacing arrangement within the hazard detector testing dispenser cup) and the mark arrangement can mechanically reduce the amount of ambient radiation that is detected by the sensors in the sensing arrangement. Each of or both of the spacing arrangement and mask arrangement may provide for an improved and optimised arrangement to detect an illumination source from the hazard detector.

In an example, the sensing arrangement may be positioned on a surface such as a printed circuit board (PCB) that includes one or more through holes corresponding to through holes in either or both of the spacing arrangement and/or the mask arrangement to enable integrated connection with the sensing arrangement so as to form a replaceable or removable device or module from the dispenser. Alternative means for integrated connection may be provided, for example, via adhesive or some other form of mechanical coupling or connection.

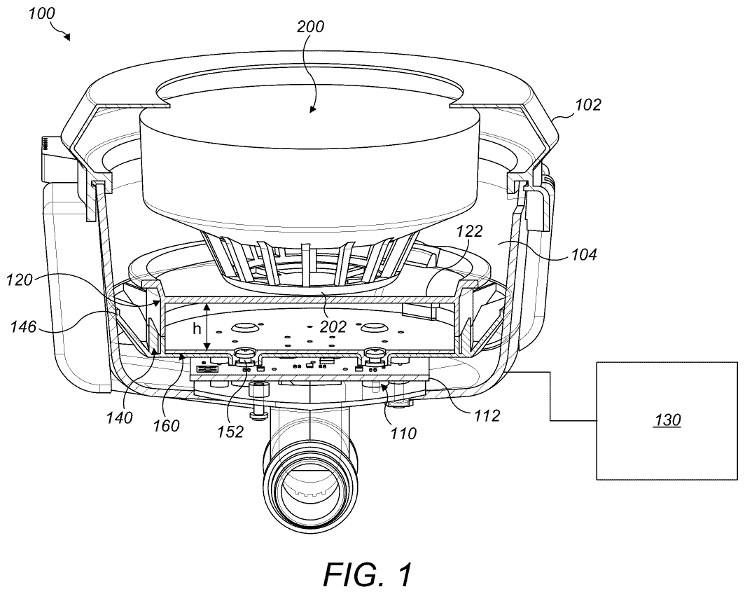

Referring to FIG. 1, there is shown an example of hazard detector testing system 100 and a hazard detector 200 to be tested. The hazard detector testing system 100 includes a dispenser or cup 102 defining an internal hazard detector test envelope 104 that is a cavity shaped to receive the hazard detector 200 and within which a functional test can be carried out.

The hazard detector system 100 further comprises a sensing arrangement 110. The sensing arrangement 110 may comprise a sensor configured to detect the output signals from the hazard detector. In an example, the sensor in the form of at least one photosensitive element configured to detect visible light of various wavelengths. The photosensitive element may be positioned on a surface of a printed circuit board (PCB) 112 or other support member to allow the photosensitive element to detect electromagnetic radiation from the an illumination source that may be located on the surface of a hazard detector 200 located above the PCB 112 when the hazard detector 200 is to undergo a test on its functionality. In other examples, there may be a plurality of photosensitive elements or an array of photosensitive elements. The photosensitive element may be configured to receive photons of light and convert the received photons into data which may be processed by a controller (not shown). In a further example, the sensing arrangement 110 may comprise at least one camera configured to record visible light of various wavelengths. The camera may be configured to record visible light and convert the received images into data which may be processed by the controller. The sensing arrangement 130 is not limited to a photosensitive element or a camera. Any device, or combination of devices, which may be configured to receive visible light may be implemented in the sensing arrangement 130. In another example, the sensing arrangement 130 may comprise at least one infrared sensor configured to detect infrared signals produced by the hazard detector. The first sensing arrangement 130 is not limited to the above mentioned sensing elements. The hazard detector 200 that is being tested using the hazard detector testing system may comprise one or a plurality of signal transmitting elements to indicate the state of the hazard detector. Any sensing element, or combination of elements, which may be configured to receive the signals produced by the hazard detector may be implemented into the sensing arrangement 130.

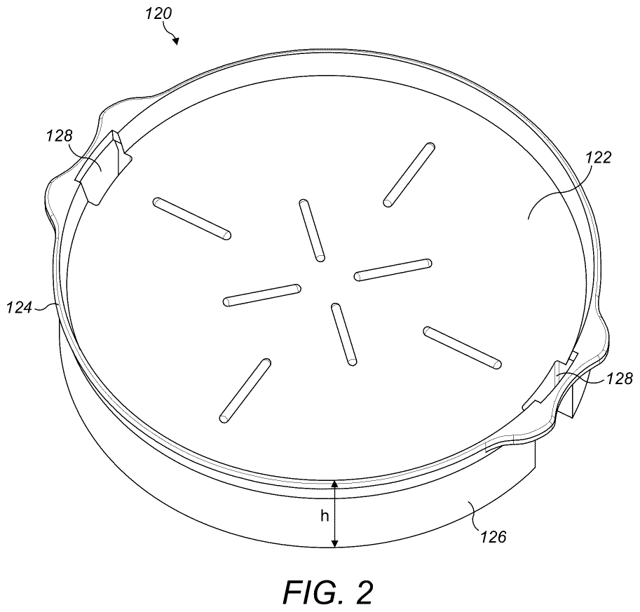

With reference also to FIG. 2, the hazard detector system 100 comprises a spacing arrangement 120. The spacing arrangement 120 is arranged to prevent the hazard detector 200 from encroaching too far into the field of view of the sensor or plurality of sensors of the sensing arrangement 110. In this example, the spacing arrangement 120 is in the form of a mechanical platform. The platform 120 is configured to engage with the hazard detector 200 and to maintain a predefined distance between the hazard detector 200 and the sensing arrangement 110 when the platform 120 is engaged with the hazard detector 200. In this example, the platform 120 comprises an upper surface 122 to engage with a lowermost surface 202 of the hazard detector 200 when a test is to be carried out on the hazard detector 200. When the hazard detector 200 is located on a ceiling in an environment such as a building, the dispenser 102 is brought towards the hazard detector 200. A user of the hazard detector testing system 100 will be aware that the dispenser 102 is positioned correctly for a test as the platform's upper surface 122 will abut the lowermost surface 202 of the hazard detector 210. In such a position the upper surface 122 may be arranged substantially parallel to the lowermost surface 202.

The platform 120 may be configured to overlay the sensing arrangement 130 such that it is positioned above the sensing arrangement 130 and between the sensing arrangement 110 and the hazard detector 200. The platform 120 comprises a wall 124 and a hazard detector engagement member 126 which comprises the upper surface 122. At least the engagement member 126 is non-opaque to allow light from the illumination source of the hazard detector 200 to pass to the sensing arrangement 120. It will be appreciated that the entire platform 120 or only portions of the platform 120 that will enable light to be adequately detected by the sensing arrangement from the illumination source of the hazard detector 200 can be non-opaque. A height h of the wall 124 defines a separation distance and at least part of the predefined distance between the hazard detector 200 and the sensing arrangement 110 includes the separation distance. In this example, the platform 120 is of a cylindrical shape with a circular cross section to substantially to match the cross sectional shape of the inner cavity of the dispenser 102. It will be appreciated that to the skilled person with the benefit of the present disclosure that the shape and construction of the spacing arrangement may vary whilst allowing for separation between a sensor on the sensing arrangement and the electromagnetic radiation source on the hazard detector 200.

The hazard detector testing system 100 as shown in FIG. 1 further comprises the stimulus generating arrangement 130. The stimulus generating arrangement 130 is configured to release a stimulus to activate an alarm state of a hazard detector 200 and may be conventional. The stimulus is to replicate a hazard in a non-hazardous fashion (e.g. heat, simulated smoke). The stimulus may vary depending on the type of hazard detector that is being tested. In an example, the stimulus generator 150 may generate a smoke, heat or carbon monoxide (CO) stimulus if the hazard detector being tested is a smoke, heat and/or CO detector respectively. The stimulus generator 130 may be capable of generating one or more of the test stimuli to test a multi-hazard detector that detects for different types of hazard such as smoke, heat and CO. A schematic of the stimulus generating arrangement 130 is shown in FIG. 1 and it will appreciated that the functionality of the stimulus generating arrangement 150 can be integrated into the hazard detector testing system 100 using methods known to those skilled in the art. In particular, the test stimulus of the stimulus generating arrangement 150 may be configured to be released into the hazard detector test envelope 104 to test the functionality of the hazard detector 200.

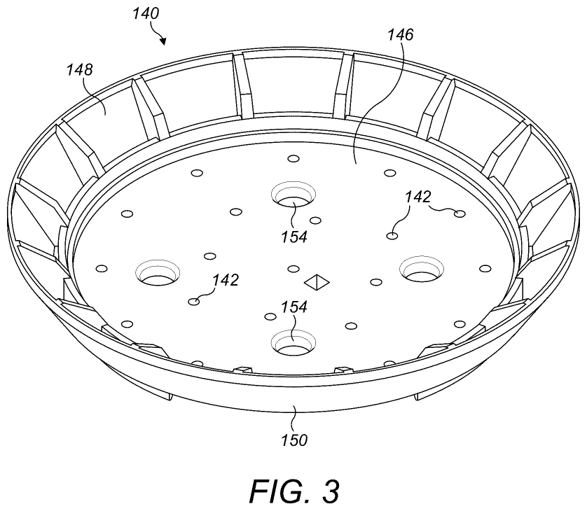

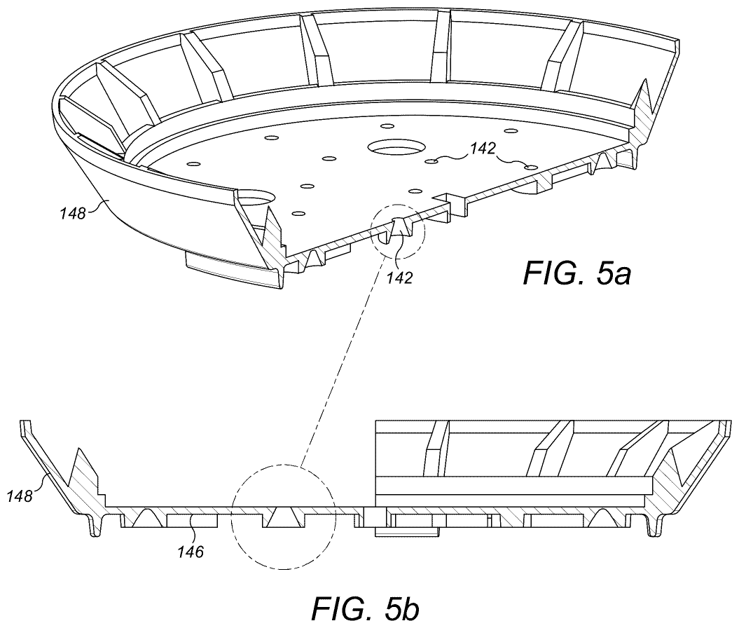

The hazard detector testing system 100 as shown in FIG. 1 along with reference to FIGS. 3, 5 and 6 further comprises a mask layer 140. Ambient electromagnetic radiation within the dispenser 102 can over-saturate photosensitive sensors in the sensing arrangement 110 to the point of not being able to discern additional electromagnetic radiation produced by the illumination source of the hazard detector 200. To counteract this, according to examples disclosed herein, masking may be provided to at least partially cover the sensing arrangement 110 and to limit the exposure from non-direct (normal to the photosensitive sensors) electromagnetic radiation. Sources of ambient electromagnetic radiation include, for example, internal heater arrangements as part of the stimulus generating unit 130 emitting electromagnetic radiation or other undesirable electromagnetic radiation passing into the detector test envelope 104.

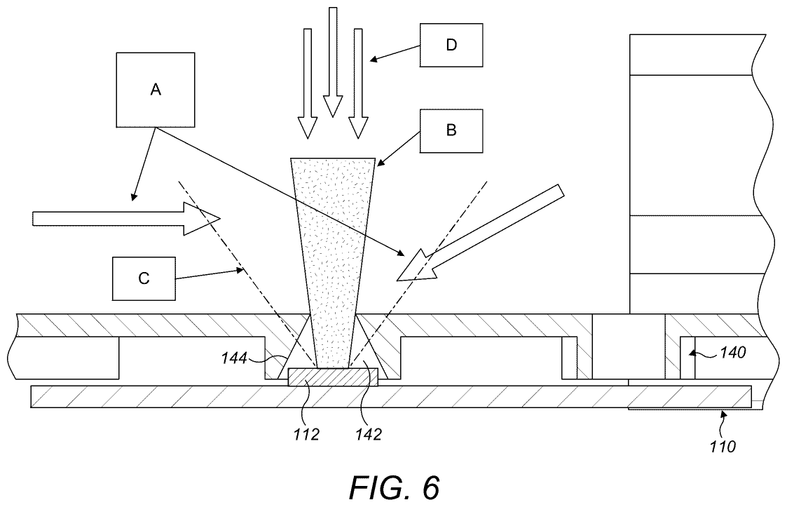

According to an example, the mask layer 140 comprises a plurality of mask arrangements each comprising an opening 142 in the form of a through hole through the mask layer 140, the opening configured to restrict a field of view of the at least one photosensitive sensor 114 provided on the sensing arrangement 110. As shown in FIG. 6, there is at least one mask arrangement 144 provided as part of a mask layer 140 that is configured to overlay the sensing arrangement 110 and reduce an amount of ambient electromagnetic radiation A detected by the sensor 112 of the sensing arrangement 110. The opening 142 of the at least one mask arrangement 144 is sized and shaped to restrict and reduce an angle of a field of view B of the at least one sensor 114 compared to the unrestricted field of view C of the sensor 112. The opening limits and prevents an amount of ambient electromagnetic radiation A (see FIG. 6) detected by and normal to the at least one sensor 114 in the sensing arrangement 110 so as to improve the detection of the electromagnetic radiation of interest D from the illumination source of the hazard detector 200. A plurality of masking arrangements 144 forming the mask layer 140 are positioned such that each opening 142 of each masking arrangement 144 are directly above and correspond to respective positions of each sensor 112 provided on the sensing layer 110. In an example, the angle of the field of view B of the sensor is reduced by a partial conical shape of the opening 142 where the base of the conical opening 142 is wider than the top of the conical opening 142.

The mask layer 140 may be formed of a material that is opaque. In an example, as shown more closely in FIGS. 1, 3, 5a, and 5b, the mask layer 140 may be formed of a base member 146 and an upstanding outwardly angled wall 148. An outer edge 150 of the mask layer 140 which may be an outer surface of the upstanding outwardly angled wall 148 substantially cooperates with an internal wall of the dispenser of the hazard detector testing system to close a portion of the hazard detection testing system in which the sensing arrangement 110 is housed.

In the example of FIG. 1, the mask layer 140 is positioned between the sensor arrangement 110 and the spacing arrangement 120. Connection with the sensor arrangement may be achieved using appropriate fasteners 152 that can be received in one or more through holes 154 that are provided in the mask layer 140 and corresponding holes in the sensing arrangement 110. Alternative means for fixing the at least one masking arrangement or the masking layer to the sensing arrangement may be provided, for example, via adhesive or some other form of mechanical coupling or connection.

As will be appreciated by the skilled person with the benefit of the present disclosure, other configurations of the mask layer 140 are possible to provide physical masking from ambient electromagnetic radiation.

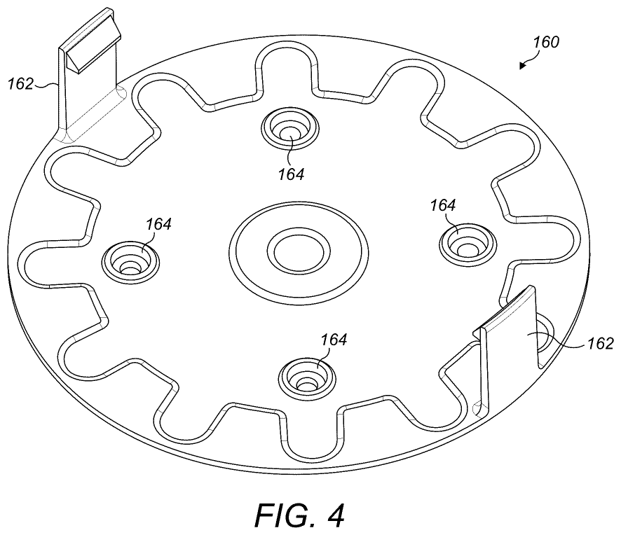

The hazard detector testing system 100 as shown in FIG. 1 along with reference to FIG. 4 may further comprise a protective layer 160 configured to seal the openings 142 of the at least one mask arrangement 144 and to provide protection to the sensing arrangement 110. The protective layer 160 is formed of material that is non-opaque at a predetermined wavelength that corresponds to the electromagnetic radiation produced by the hazard detector 200 so that the sensing arrangement 110 is able to detect the electromagnetic radiation. The protective layer 160 may be releasably connected and latching through upstanding releasable connectors 162 integrated with the protection layer 160 to corresponding portions 128 (see FIG. 2) in the platform 120 to form a base for the platform 120 whilst also providing protection for the sensing arrangement 110. Connection with the sensor arrangement 110 and mask layer 140 may be achieved using the fasteners 152 that are received in one or more through holes 164 provided in the protective layer 140, the one or more through holes 154 that are provided in the mask layer 140, and corresponding holes in the sensing arrangement 110. Although the protective layer also serves to connect the spacing arrangement 120 within the dispenser 102 of FIG. 1, other mechanisms for mechanically fixing the sensing arrangement within the hazard detector testing apparatus will be appreciated by the skilled person with the benefit of the present disclosure. In addition, other configurations of the protective layer 160 are possible to provide protection for the sensors in the sensing arrangement 110. As is apparent, the combination of sensing arrangement 110, spacing arrangement 120, mask layer 140 and protective layer 160 may be provided in a layer structure which is compact and can be formed of an integrated single unit that may be connected by fasteners and or engagement members. The unit may be connected to a dispenser, for example, to a base of the dispenser using appropriate fasters or connection mechanisms. It will also be appreciated that the functionality of each of the spacing arrangement, mask layer and protective layer is achievable independently of each other.

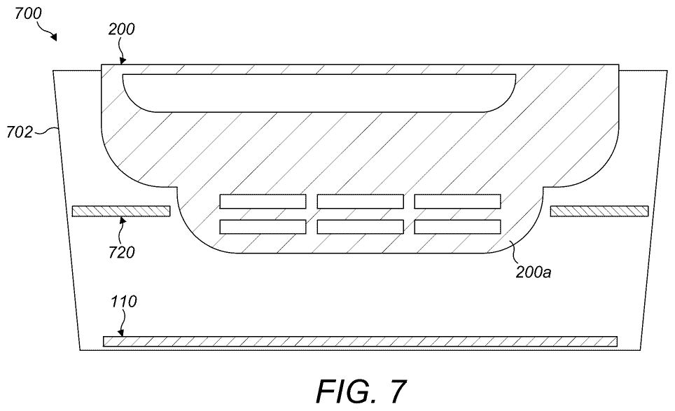

In an alternative example of a hazard detector testing system 700 that includes an alternative spacing arrangement, reference is made to FIG. 7. Instead of a platform as in the example in FIG. 1, a spacing arrangement may be in the form of a ring structure 720 mounted to and around an inner wall of a dispenser 702 of the hazard detector testing system and the sensing arrangement 110. The ring structure 720 is capable of engaging with a surface of a hazard detector 200 that may be the same or similar to that shown and described with reference to FIG. 1. Similarly to the first example of FIG. 1, the ring structure 720 which is another form of spacing arrangement can limit the insertion depth of the detector to the sensing arrangement when a test is to be conducted. The ring structure 720 may comprise an opening within which a lower part 200a of the detector containing an illumination source passes through or another means to allow electromagnetic radiation from the illumination source to pass to and be detected adequately by sensors in the sensing arrangement 110. A stimulus generating arrangement (not shown) is provided in order to provide similar functionality as described with reference to FIG. 1. A corresponding mask arrangement or layer and/or protective arrangement or layer (not shown) may be provided.

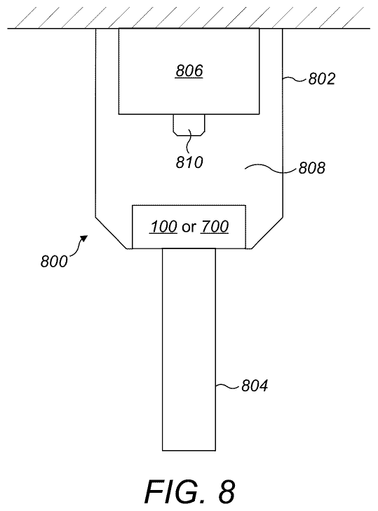

Referring to FIG. 8, there is shown a hazard detector testing apparatus 810. The hazard detector testing tool 800 comprises dispenser 802 that includes an elongate pole 804 that may be attachable to the dispenser 802 to allow the test to be carried out on a hazard detector 806 that may be located on the ceiling of an environment. In an example, the dispenser 802 is formed an open topped housing including a bottom and sidewall forming a cavity 808 to receive a hazard detector 806. The open topped housing may be transparent. The hazard detector 806 may comprise a light emitting device 810 such as a light emitting diode which emits, for example, an LED light signal when in an alarm state. In one example, this may be a particular colour light signal such as a red signal. In addition or alternatively, the detector 806 may comprise another alert condition indicator. In an example, the hazard detector testing system 100, or the hazard detector testing system 700 is located within the cavity and attached to the open topped housing to enable a hazard alert condition to be automatically detected. The system 100 or 700 including a plurality of photosensitive elements positioned at various locations, and the spacing arrangement and/or corresponding mask layer can be used to automatically detect electromagnetic signals output from a wide variety of hazard detectors.

In addition to the examples described in detail above, the skilled person will recognize that various features described herein can be modified and/or combined with additional features, and the resulting additional examples can be implemented without departing from the scope of the system of the present disclosure, as this specification merely sets forth some of the many possible example configurations and implementations for the claimed solution.

The following paragraphs provide a list of additional embodiments which may serve as basis for claims in this application or in any subsequently filed divisional application(s).

Embodiment 1: A hazard detector testing system comprising: a sensing arrangement configured to detect electromagnetic radiation produced by a hazard detector; and a spacing arrangement configured to engage with the hazard detector and to maintain a predefined distance between the hazard detector and the sensing arrangement when the spacing arrangement is engaged with the hazard detector.

Embodiment 2: The system of Embodiment 1, wherein the spacing arrangement is in the form of a platform or a ring structure or includes one or more walls and/or a plurality of columns.

Embodiment 3: The system of Embodiment 1, wherein the predefined distance is provided to prevent the hazard detector from encroaching too far into the field of view of one or more sensors provided on the sensing arrangement.

Embodiment 4: The system of Embodiments 1, 2 or 3. wherein the electromagnetic radiation is emitted from an emitter positioned on a surface of the hazard detector.

Embodiment 5: The system of any preceding Embodiment, wherein the electromagnetic radiation is light that is detectable by sensing arrangement.

Embodiment 6: The system of any preceding Embodiment, wherein the sensing arrangement is configured to detect an intensity and/or spectral content of visible light produced by the hazard detector.

Embodiment 7. The system of any preceding Embodiment, wherein the spacing arrangement is a platform

Embodiment 8: The system of Embodiment 7, wherein the platform is configured to overlay the sensing arrangement.

Embodiment 9: The system of Embodiment 7 or 8, wherein platform comprises a surface to engage with a surface of the hazard detector.

Embodiment 10: The system of Embodiment 9, wherein the surface that is to engage with the hazard detector surface is substantially parallel to the surface of the hazard detector. Embodiment 11: The system of any one of Embodiments 7 to 10, wherein the platform comprises a wall defining a separation distance and a hazard detector engagement member.

Embodiment 12: The system of Embodiment 11, wherein at least part of the predefined distance includes the separation distance.

Embodiment 13: The system of any preceding Embodiment, further comprising a stimulus generating arrangement configured to produce a test stimulus to test the hazard detector, wherein the test stimulus is to activate an alarm state of the hazard detector.

Embodiment 14: The system of any preceding Embodiment, further comprising at least one mask arrangement comprising an opening configured to restrict a field of view of at least one sensor provided on the sensing arrangement.

Embodiment 15: The system of Embodiment 14, wherein the opening of the at least one mask arrangement is sized to restrict an angle of a field of view of the at least one sensor so as to limit an amount of ambient electromagnetic radiation detected by the at least one sensor.

Embodiment 16: The system of Embodiment 14 or 15, wherein the opening of the at least one mask arrangement is sized to restrict the angle of a field of view of the at least one sensor so as to limit an amount of ambient electromagnetic radiation normal to the at least one sensor.

Embodiment 17: The system of Embodiment 14, 15 or 16, wherein the at least one mask arrangement is provided as part of a mask layer that is configured to overlay the sensing arrangement and reduce an amount of ambient electromagnetic radiation detected by the sensing arrangement.

Embodiment 18: The system of Embodiment 16, wherein the mask layer is opaque.

Embodiment 19: The system of Embodiment 17 or 18, wherein an outer edge of the mask layer substantially cooperates with an internal wall of the hazard detector testing system to close a portion of the hazard detection testing system in which the sensing arrangement is housed.

Embodiment 20: The system of any of Embodiments 14 to 19, wherein there are a plurality of mask arrangements and each of the mask arrangements is positioned to correspond to respective one of a plurality of sensors provided on the sensing arrangement.

Embodiment 21: The system of any of Embodiments 17 to 20, wherein the mask layer is positioned between the sensor arrangement and the spacing arrangement.

Embodiment 22: The system of any of Embodiments 14 to 21, further comprising a protective layer configured to seal the opening of the at least one mask arrangement and to provide protection to the sensing arrangement.

Embodiment 23: The system of Embodiment 22, wherein the protective layer is non-opaque at a predetermined wavelength that corresponds to the electromagnetic radiation produced by the hazard detector so that the sensing arrangement is able to detect the electromagnetic radiation.

Embodiment 24: The system of Embodiment 22 or 23, wherein the protective layer is positioned on the at least one mask arrangement which is positioned between the sensor arrangement and the spacing arrangement.

Embodiment 25: Apparatus for spacing a hazard detector from a hazard detector testing apparatus during a test on the hazard detector, comprising: a spacing arrangement of any one of the preceding claims, configured to engage a surface of the hazard detector and to maintain a predefined distance between an emitter of electromagnetic radiation on the hazard detector and a sensing arrangement in the hazard detector testing apparatus when the hazard detector testing apparatus is positioned to carry out a test on the hazard detector.

Embodiment 26: The spacing apparatus of Embodiment 25, wherein the arrangement comprises a mechanism for mechanically fixing within the hazard detector testing apparatus.

Embodiment 27: Apparatus for restricting a field of view of at least one sensor provided on a sensing arrangement in a hazard detecting apparatus that is to detect electromagnetic radiation emitted by a hazard detector; comprising: at least one mask arrangement of any one of Embodiments 14 to 24, comprising an opening configured to restrict a field of view of at least one sensor provided on the sensing arrangement in the hazard detector testing apparatus when the hazard detector testing apparatus is positioned to carry out a test on the hazard detector.

Embodiment 28: The restricting apparatus of Embodiment 27, wherein the at least one mask arrangement comprises means for fixing the at least one masking arrangement to the sensing arrangement.

Embodiment 29: A hazard detector testing system comprising: a sensing arrangement configured to detect electromagnetic radiation produced by a hazard detector; and at least one mask arrangement comprising an opening configured to restrict a field of view of at least one sensor provided on the sensing arrangement.

Embodiment 30: The system of Embodiment 29, wherein the sensing arrangement comprises at least one sensor, and the opening of the at least one mask arrangement defines an angle of the field of view of the at least one sensor to limit the amount of ambient electromagnetic radiation detected by the at least one sensor.

Embodiment 31: The system of Embodiment 29, wherein the opening of the at least one mask arrangement defines the angle of the field of view of the at least one sensor to limit the amount of ambient electromagnetic radiation normal to the at least one sensor.

Embodiment 32: The system of Embodiment 29, 30 or 31, wherein the at least one mask arrangement is provided as part of a mask layer that is configured to overlay the sensing arrangement.

Embodiment 33: The system of Embodiment 32, wherein the mask layer is opaque.

Embodiment 34: The system of Embodiment 31 or 33, wherein an outer edge of the mask layer substantially cooperates with an internal wall of the hazard detector testing system to close a portion of the hazard detection testing system in which the sensing arrangement is housed.

Embodiment 35: The system of any one of Embodiments 29 to 34, wherein there are a plurality of mask arrangements and each of the mask arrangements is positioned to correspond to respective one of a plurality of sensors provided on the sensing arrangement.

Embodiment 36: The system of any one of Embodiments 29 to 34, further comprising a protective layer configured to seal the opening of the at least one mask arrangement and to provide protection to the sensing arrangement.

Embodiment 37: The system of Embodiment 36, wherein the protective layer is non-opaque at a predetermined wavelength that corresponds to the electromagnetic radiation produced by the hazard detector so that the sensing arrangement is able to detect the electromagnetic radiation.

Embodiment 38: A hazard detector test tool comprising: a dispenser to receive a hazard detector during a test, the dispenser further comprising: the hazard detecting testing system of any of Embodiments 1 to 24; the spacing arrangement of Embodiments 25 to 26; the restricting apparatus of Embodiments 27 to 28; or the hazard detecting testing system of any of Embodiments 29 to 36.

Embodiment 39: The tool of Embodiment 38, when comprising the hazard detecting testing system of any of claims 1 to 24 or the hazard detecting testing system of any of claims 29 to 36, wherein the hazard detector testing system is in the form of an interconnected device positioned in the dispenser.

Embodiment 40: The system of Embodiment 38 or 39, wherein the dispenser comprises an open-topped housing including a bottom and sidewall forming a cavity for receiving the hazard detector, and the test tool further comprises an elongate pole for connection to the dispenser.

1. A hazard detector testing system comprising:
a sensing arrangement configured to detect electromagnetic radiation produced by a hazard detector; and
a spacing arrangement configured to engage with the hazard detector and to maintain a predefined distance between the hazard detector and the sensing arrangement when the spacing arrangement is engaged with the hazard detector;
wherein the spacing arrangement is in the form of a platform or a ring structure or includes one or more walls and/or a plurality of columns.

2.-4. (canceled)

5. The system of any preceding claim 1, wherein the platform is configured to overlay the sensing arrangement.

6. The system of claim 5, wherein platform comprises a surface to engage with a surface of the hazard detector and optionally, wherein the surface that is to engage with the hazard detector surface is substantially parallel to the surface of the hazard detector.

7. (canceled)

8. The system of claim 1, wherein the platform comprises a wall defining a separation distance and a hazard detector engagement member and optionally, wherein the surface that is to engage with the hazard detector surface is substantially parallel to the surface of the hazard detector.

9. (canceled)

10. (canceled)

11. The system of claim 1, further comprising at least one mask arrangement comprising an opening configured to restrict a field of view of at least one sensor provided on the sensing arrangement.

12. The system of claim 11, wherein the opening of the at least one mask arrangement is sized to restrict an angle of a field of view of the at least one sensor so as to limit an amount of ambient electromagnetic radiation detected by the at least one sensor.

13. The system of claim 11, wherein the opening of the at least one mask arrangement is sized to restrict the angle of a field of view of the at least one sensor so as to limit an amount of ambient electromagnetic radiation normal to the at least one sensor.

14. The system of claim 11, wherein the at least one mask arrangement is provided as part of a mask layer that is configured to overlay the sensing arrangement and reduce an amount of ambient electromagnetic radiation detected by the sensing arrangement.

15. The system of claim 14, wherein the mask layer is opaque.

16. The system of claim 14, wherein an outer edge of the mask layer substantially cooperates with an internal wall of the hazard detector testing system to close a portion of the hazard detection testing system in which the sensing arrangement is housed.

17. The system of claim 11, wherein there are a plurality of mask arrangements and each of the mask arrangements is positioned to correspond to respective one of a plurality of sensors provided on the sensing arrangement.

18. The system of claim 14, wherein the mask layer is positioned between the sensor arrangement and the spacing arrangement.

19. The system of claim 11, further comprising a protective layer configured to seal the opening of the at least one mask arrangement and to provide protection to the sensing arrangement.

20. The system of claim 19, wherein the protective layer is non-opaque at a predetermined wavelength that corresponds to the electromagnetic radiation produced by the hazard detector so that the sensing arrangement is able to detect the electromagnetic radiation.

21. The system of claim 19, wherein the protective layer is positioned on the at least one mask arrangement which is positioned between the sensor arrangement and the spacing arrangement.

22. Apparatus for spacing a hazard detector from a hazard detector testing apparatus during a test on the hazard detector, comprising:
a spacing arrangement of claim 1, configured to engage a surface of the hazard detector and to maintain a predefined distance between an emitter of electromagnetic radiation on the hazard detector and a sensing arrangement in the hazard detector testing apparatus when the hazard detector testing apparatus is positioned to carry out a test on the hazard detector.

23. The spacing apparatus of claim 22, wherein the arrangement comprises a mechanism for mechanically fixing within the hazard detector testing apparatus.

24. Apparatus for restricting a field of view of at least one sensor provided on a sensing arrangement in a hazard detecting apparatus that is to detect electromagnetic radiation emitted by a hazard detector; comprising:
at least one mask arrangement of claim 11, comprising an opening configured to restrict a field of view of at least one sensor provided on the sensing arrangement in the hazard detector testing apparatus when the hazard detector testing apparatus is positioned to carry out a test on the hazard detector.

25. The restricting apparatus of claim 24, wherein the at least one mask arrangement comprises means for fixing the at least one masking arrangement to the sensing arrangement.

26.-34. (canceled)

35. A hazard detector test tool comprising:
a dispenser to receive a hazard detector during a test, the dispenser further comprising: the hazard detecting testing system of claim 1; a spacing arrangement configured to engage a surface of a hazard detector and to maintain a predefined distance between an emitter of electromagnetic radiation on the hazard detector and a sensing arrangement in a hazard detector testing apparatus when the hazard detector testing apparatus is positioned to carry out a test on the hazard detector; or a restricting apparatus comprising at least one mask arrangement comprising an opening configured to restrict a field of view of at least one sensor provided on the sensing arrangement in the hazard detector testing apparatus when the hazard detector testing apparatus is positioned to carry out a test on the hazard detector and optionally wherein, the hazard detector testing system is in the form of an integrated single unit positioned in the dispenser.

36. (canceled)

37. (canceled)
